(19) United States
(12) Patent Application Publication
(10) Pub. No.: US 2024/0295811 A1
(43) Pub. Date: Sep. 5, 2024

(54) ORGANOMETALLIC PHOTORESISTS AND DEVELOPMENT METHODS

(71) Applicant: Feng Lu, Irvine, CA (US)

(72) Inventor: Feng Lu, Irvine, CA (US)

(21) Appl. No.: 18/591,482

(22) Filed: Feb. 29, 2024

Related U.S. Application Data
(60) Provisional application No. 63/449,695, filed on Mar. 3, 2023.

(51) Int. Cl. G03F 7/004; G03F 7/20

(52) U.S. Cl. CPC G03F 7/0042; G03F 7/0048; G03F 7/2004

(57) ABSTRACT

Organometallic photoresists and development methods, particularly organometallic tin photoresists for extreme ultraviolet radiation (EUV) patterning and development methods, are described. The radiation sensitive organometallic photoresists RₐM_{b}L_{c} include Sn, In, Sb, Bi, Mn, V, Ti, Cr, Se, Te, Zr, Hf, Ga, or Ge compounds, wherein R is a substituted or unsubstituted cycloalkenyl group with 3 to 20 carbon atoms; L is ligand; a, b, c≥1. The development methods for photolithography patterning comprise sublimation and vaporization under ambient vacuum and temperature.

### CROSS REFERENCE TO RELATED APPLICATIONS

This application claims priority to U.S. provisional patent application No. 63/449,695 filed on Mar. 3, 2023 to Lu, entitled “Organometallic photoresists and development methods”, of which is entirely incorporated herein by reference.

### FIELD OF INVENTION

The present invention relates to organometallic photoresists and development methods, particularly organometallic tin photoresists for extreme ultraviolet radiation (EUV) photolithography patterning and development methods.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light adsorption because metals have high adsorption capacity of ultraviolet radiation with various carbon-metal (C-M) bond dissociation energy (BDE), and then can be used as photoresists and/or the precursors for photolithography at smaller level (e.g., <7 nm), which is of great interests for radiation lithography. Among those promising advanced materials, particularly organometallic tin compounds can provide photoresist patterning with significant advantages, such as improved resolution, sensitivity, etch resistance, and lower line width/edge roughness without pattern collapse because of strong EUV radiation adsorption of tin, which have been demonstrated.

The general development methods for photolithography patterning includes wet liquid solvents development method, dry gaseous development method. Wet liquid solvents development method utilizes liquid organic solvents or aqueous solvents to remove exposed portions or unexposed portions of photoresists, which corresponding to positive or negative patterning. Organometallic photoresist which are suitable for sublimation or vaporization under ambient vacuum and temperature, can be deposited on the surface of semiconductor substrate by chemical vapor deposition (CVD), physical vapor deposition (PVD), atomic layer deposition (ALD), or spin-on coating, or other approaches. After exposure to ultraviolet light (e.g., EUV 13.5 nm), exposed or irradiated portions of organometallic photoresists become non-sublimized, or non-volatile, or insoluble metallic complexes, or polymetallic network complexes, such as metal oxides, or metal oxide/hydroxide network complexes. While unexposed portion can be selectively removed by sublimation or vaporization for pattern development under ambient vacuum and temperature. The sublimation and vaporization development methods avoid the usage of liquid organic solvents or aqueous solutions from wet development, or dry development method with gases like hydrogen halides, with lower manufacturing cost and environmentally friendly development. The sublimation and vaporization development methods also may avoid pattern collapses and defects due to rinse process.

### SUMMARY

In a first aspect, the present invention pertains to organometallic photoresists and development methods, particularly organometallic tin photoresists for extreme ultraviolet (EUV) patterning and development methods. The present invention is to provide organometallic compounds as photoresists for photolithography patterning, particularly EUV and DUV. The present invention is further to provide sublimation and vaporization development methods for patterning development under ambient vacuum and temperature without pattern collapses and defects during microelectronic patterning, particularly for EUV lithography <7 nm.

In another aspect, the invention pertains to radiation sensitive organometallic photoresists RₐM_{b}L_{c}, which can convert to un-sublimized/un-vaporized metallic complexes or polymetallic network complexes (e.g., metal oxides) after exposure to ultraviolet light (e.g., EUV, DUV). Meanwhile unexposed organometallic photoresists can be removed by sublimation or vaporization under ambient vacuum and temperature (e.g., high vacuum and temperature). The invention pertains to radiation sensitive organometallic photoresists RₐM_{b}L_{c} including but not limited to organometallic tin (Sn), indium (In), antimony (Sb), bismuth (Bi), manganese (Mn), vanadium (V), titanium (Ti), chromium (Cr), selenium (Se), tellurium (Te), zirconium (Zr), hafnium (Hf), gallium (Ga), or germanium (Ge) compounds, for example, sandwich or half-sandwich compounds; wherein R is a substituted or unsubstituted alkyl, alkenyl, alkynyl, cycloalkyl, or cycloalkenyl group with 1 to 20 carbon atoms; L is ligand such as alkoxide, amide, ester, hydroxide, nitride, halide, or thiolate; a, b, c≥1.

In a further aspect, the invention pertains to the sublimation and vaporization development methods, which may have superiority for smaller features of photolithography patterning at <7 nm, compared with conventional wet liquid solvent development methods and dry gaseous development methods. The wetting and surface tension on the semiconductor substrate surface make the conventional development methods difficult at smaller patterning <7 nm, particularly 1-3 nm, along with pattern collapses and defects due to the liquid flows or gaseous flows, and rinse process. Additionally, the conventional wet and dry development methods may not remove all the unexposed portions of organometallic photoresists due to the smaller pitch and space between two adjacent pitches at smaller scale, or <100% etch yield.

Particularly, the invention pertains to highly pure radiation sensitive organometallic tin (or organotin) photoresists, which may be suitable for EUV or DUV photolithography, and/or as the precursors for EUV or DUV photolithography, including but not limited to, cycloalkenyl-containing organometallic tin compounds, such as (cyclopentadienyl)tin compounds. In some embodiments, organometallic tin photoresists can be sublimized or vaporized, but not decomposed, under high vacuum and temperature like from 20 to 300° C.

In some embodiments, cycloalkenyl group comprises a substituted and unsubstituted C4 to C8 cyclic unsaturated organic groups including at least one double bond. In some embodiments, cycloalkenyl group is one or more selected from the following:

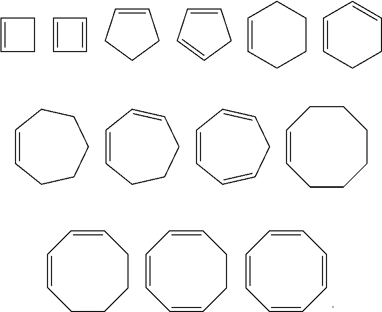

In some embodiments, cycloalkenyl-containing organometallic photoresists comprise cyclopentadienyl, or cycloheptatrienyl. Cyclopentadienyl comprises cyclopentadienyl C₅H₅ (or Cp), or substituted cyclopentadienyl C₅H₄R′, C₅H₃R′₂, C₅H₂R′₃, C₅HR′₄, or C₅R′₅ with hapticity of η¹, η², η³, η₄, or η⁵ of isomers. Cycloheptatrienyl comprises cycloheptatrienyl C₇H₇ group, or substituted cycloheptatrienyl C₇H₆R′, C₇H₅R′₂, C₇H₄R′₃, C₇H₃R′₄, C₇H₂R′₅, C₇HR′₆, or C₇R′₇ group with hapticity of η¹, η², η³, η₄, η⁵, η⁶, or η⁷ of isomers; wherein R′ is H, a substituted or unsubstituted alkyl, alkenyl, alkynyl, or cycloalkyl group with 1 to 20 carbon atoms, or a substituted or unsubstituted aryl group with 6-20 carbon atoms, or amino, cyano, ether, ester, halide, nitro, silyl, thiol, or carbonyl group.

In an additional aspect, the invention pertains to radiation sensitive organometallic tin photoresists represented by FIG. 1, particularly cycloalkenyl-containing organometallic tin compounds such as (cyclopentadienyl)tin and (cycloheptatrienyl)tin compounds. In some embodiments, FIG. 1 also represents the similar molecular structures of organometallic indium (In), antimony (Sb), bismuth (Bi), manganese (Mn), vanadium (V), titanium (Ti), chromium (Cr), selenium (Se), tellurium (Te), zirconium (Zr), hafnium (Hf), gallium (Ga), or germanium (Ge) compounds with appropriate modifications based on oxidation states.

In some embodiments, organometallic tin photoresists, particularly, cycloalkenyl-containing photoresists like cyclopentadienyl-containing or cycloheptatrienyl-containing oxide hydroxide (stannonic acid), anhydride, hydroxide, alkoxides, amides, distannoxane (oxo), oxides, or esters, are suitable for EUV and DUV photolithography, and for sublimation and vaporization development processing under ambient vacuum and temperature.

In other aspects, the invention pertains to the methods for organometallic photoresists deposition on a surface of semiconductor substrate by wet deposition like spin-on coating, or dry deposition like chemical vapor deposition, physical vapor deposition, atomic layer deposition, or other approaches.

The sublimation and vaporization development methods overcome the drawbacks of pattern collapses and defects from wet organic and aqueous development solution, and dry development of hydrogen halides. The photosensitivity and thermostability of organometallic photoresists determine high resolution and efficiency of photolithography. In further embodiments, the sublimation deposition method may not need the general baking process from wet deposition method.

In some embodiments, the invention pertains to photolithography irradiation process, which can be conducted under oxygen source atmosphere, including but not limited to, air or oxygen (O₂), ozone (O₃), hydrogen peroxide (H₂O₂) atmosphere, or water (H₂O) which can result in or enhance the oxidization of irradiated organometallic photoresist to form metal oxide or polymetallic oxide networks under some circumstances. In additional embodiments, during or followed irradiation, organometallic photoresist can contact with reactive gaseous atmosphere such as H₂S, SO₂, S₈, CO₂, CO, HCOOH, NH₃, PH₃, or SiH₄, which can increase the contrast between irradiated and unirradiated portions of organometallic photoresists.

In some embodiments, the conventional wet development process with organic solvents or aqueous solutions, for example, dipped in conventional 2-heptaone bath for forty seconds to remove unexposed portions of photoresist film to develop a negative-tone pattern, may be replaced by sublimation or vaporization under high vacuum and appropriate temperature, which can reduce the pattern collapse. For <7 nm pitch pattern, the issues from wet solvents development method after exposure like wetting and solvent surface tension effect may block the removal of unexposed portion of photoresist between two adjacent pitches at pretty small scale like≤3 nm. In additional embodiments, the rinse process after development, such as the treatment of patterned film by aqueous tetramethylammonium hydroxide (TMAH) solution for 10-30 seconds, may be omitted. Without solvent development and rinse process can significantly reduce cost and pollution, improve resolution efficiency of pattern and protect the environment.

In a further aspect, the invention relates to radiation sensitive organometallic photoresists, particularly organotin photoresists, which can be efficiently patterned in the presence of ultraviolet light, extreme ultraviolet (EUV) light, deep ultraviolet radiation (DUV), electron beam radiation, X-ray radiation, or ion-beam radiation to form high resolution patterns with low line width roughness at <7 nm, and with high resolution, low dose and large contrast for <7 nm.

### BRIEF DESCRIPTION OF THE DRAWINGS

FIG. 1 represents chemical formulas of organometallic tin compounds as photoresists or precursors, wherein R, R¹, R², R³ are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; X=F, Cl, Br, or I; E=O, S, Se, or Te; for example, (cyclopentadienyl)tin or (cycloheptatrienyl)tin compounds.

FIG. 2 is photolithography patterning process including organometallic photoresist deposition (100), PEB (101), exposure (102), sublimation or vaporization development (103).

FIG. 3 illustrates conventional wet liquid solvent development methods.

FIG. 4 illustrates liquid solvent wetting and surface tension effect on the surface of semiconductor substrate, which may block the removal of unexposed organometallic photoresists after exposure due to smaller pitch (e.g., <3 nm) and distance between two adjacent pitches.

FIG. 5 illustrates organometallic tin photoresist radiation photolithography patterning processing on the surface of semiconductor substrate surface.

### DETAILED DESCRIPTION

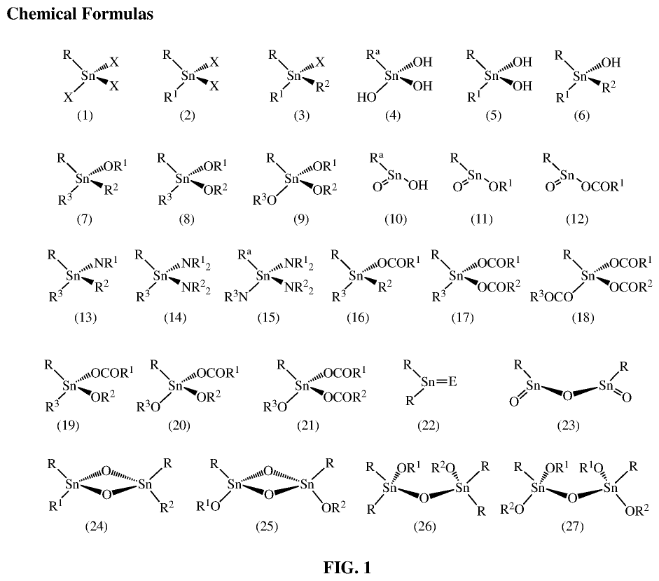

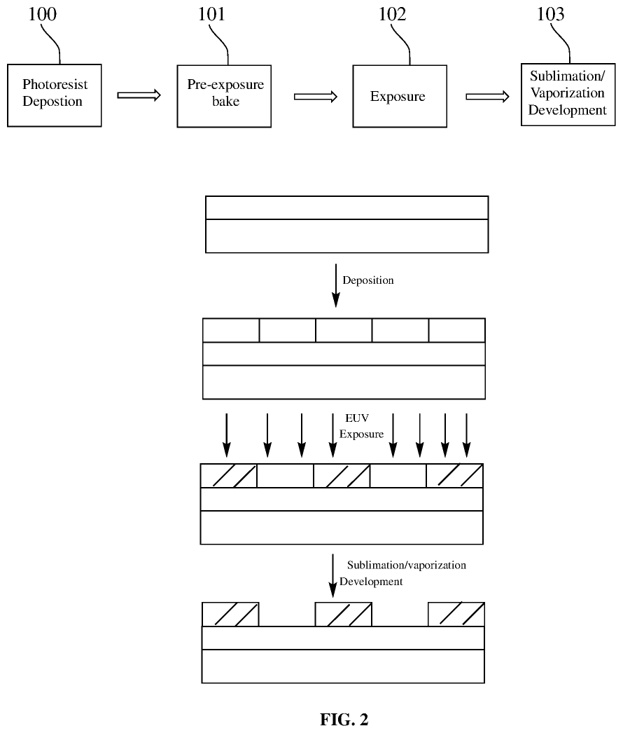

The present invention pertains to organometallic photoresists and development methods, particularly organometallic tin photoresists for extreme ultraviolet (EUV) patterning. The radiation sensitive organometallic photoresists represented by RₐM_{b}L_{c}, wherein R is a substituted or unsubstituted alkyl, alkenyl, alkynyl, cycloalkyl, or cycloalkenyl group with 1 to 20 carbon atoms; M is metal including Sn, In, Sb, Bi, Mn, V, Ti, Cr, Se, Te, Zr, Hf, Ga, or Ge; L is organic ligand such as alkoxide, amide, ester, halide, hydroxide, or thiolate group; a, b, c≥1. The development methods for photolithography patterning comprise sublimation or vaporization under ambient vacuum and temperature. The present invention is further to provide organometallic tin compounds represented by FIG. 1 as photoresists or precursors, particularly cycloalkenyl-containing such as (cyclopentadienyl)tin, (cycloheptatrienyl)tin, for EUV photolithography with higher resolution, sensitivity, solubility, stability, shelf life, and lower line width roughness without pattern collapse during microelectronic patterning. (Cyclopentadienyl)tin compounds comprise cyclopentadienyl C₅H₅ (or Cp) group, or substituted cyclopentadienyl C₅H₄R′, C₅H₃R′₂, C₅H₂R′₃, C₅HR′₄, or C₅R′₅ with hapticity of η¹, η², η³, η₄, or η⁵ of isomers. (Cycloheptatrienyl)tin compounds comprise cycloheptatrienyl C₇H₇ group, or substituted cycloheptatrienyl C₇H₆R′, C₇H₅R′₂, C₇H₄R′₃, C₇H₃R′₄, C₇H₂R′₅, C₇HR′₅, or C₇R′₇ group with hapticity of η¹, η², η³, η₄, η⁵, η⁶, or η⁷ of isomers; wherein R′ is H, a substituted or unsubstituted alkyl, alkenyl, alkynyl, or cycloalkyl group with 1 to 20 carbon atoms, or a substituted or unsubstituted aryl group with 6-20 carbon atoms, or amino, cyano, ether, ester, halide, nitro, silyl, thiol, or carbonyl group.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl” or “alkyl group” refers to a saturated linear or branched-chain hydrocarbon of 1 to 20 carbon atoms, e.g., methyl, ethyl, propyl, butyl. The term “alkenyl” refers to an aliphatic hydrocarbon of 2 to 20 carbon atoms containing at least one double bond. The term “alkynyl” refers to an aliphatic hydrocarbon of 2 to 20 carbon atoms containing at least one triple bond. The term “cycloalkyl” refers to cyclic aliphatic hydrocarbon of 3 to 20 carbon atoms, e.g., cyclopropyl, cyclobutyl, cyclohexyl. The term “aryl” refers to unsubstituted or substituted aromatic group with 6-20 carbon atoms, e.g., phenyl, benzyl. The substituted group include, but not limited to, amide, amine, cyano, ether, cyclic ether, ester, cyclic ester, halide, imine, nitro, silyl, thiol, or carbonyl group. The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like. The term “alkoxide” or “alkoxyl” refers to —OR group.

The term “amine” refers to primary (—NH₂), secondary (—NHR) group. The term “amide” refers to —NRR′ group. The term “cyclic amine” refers to [R—NH—R′], wherein [R—R′] is cyclic substituted or unsubstituted C3 to C8 organic groups.

The term “ether” refers to the R—O—R′ group. The term “cyclic ether” refers to the [R—O—R′], wherein [R—R′] is cyclic substituted or unsubstituted C3 to C8 organic groups. The term “ester” refers to the R—(C—O)—O—R′ group. The term “cyclic ester” refers to the [R—(C—O)—O—R′], wherein [R—R′] is cyclic substituted or unsubstituted C4 to C8 organic groups.

The term “halide” refers to the F, Cl, Br, or I. The term “nitro” refers to the —NO₂. The term “silyl” refers to the —SiR—, —SiR₂—, or —SiR₃ group. The term “thiol” refers to —SH group. The term “thiolate” refers to —SR group. The term “carbonyl” refers to the —C—O group. The term “oxo” refers to —O—, or ═O. In the above described, R, R′ are independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms.

In some embodiments, the term “substituted” refers to replacement of a hydrogen atom with a C1 to C20 alkyl group, a C1 to C20 alkene group, a C1 to C20 alkyne group, a C1 to C20 cycloalkyl group, a C6 to C20 aryl group, or other relevant groups.

The terms “η¹” refers to one carbon atom bonded to one metal atom. The terms “η²” refers to two carbon atoms bonded to one metal atom. The terms “η³” refers to three carbon atoms bonded to one metal atom. The terms “η⁴” refers to four carbon atoms bonded to one metal atom.

The terms “η⁵” refers to five carbon atoms bonded to one metal atom. The terms “η⁶” refers to six carbon atoms bonded to one metal atom. The terms “η⁷” refers to seven carbon atoms bonded to one metal atom. The terms “η⁸” refers to eight carbon atoms bonded to one metal atom. For example, η¹, η⁵, and η⁷ are correspondingly depicted as following (M=metal):

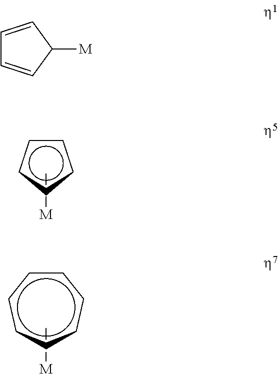

EUV lithography is under the development for the mass production of next generation <7 nm node. EUV photoresists are required to achieve higher performance, higher sensitivity and resolution, and cost reduction.

EUV light has been applied for photolithography at about 13.5 nm. The EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features. For small feature sizes like <7 nm such as 1-3 nm, the conventional chemically amplified (CA) organic polymer photoresists encounter critical issues such as poor EUV light adsorption, low resolution, high line edge roughness (LER), increased pattern collapses and defects. In order to overcome the disadvantages from organic polymer photoresists, organometallic photoresists and relevant organometallic photosensitive compositions, particularly for EUV, have been called for.

Organometallic photoresists are used in EUV lithography because metals have high adsorption capacity of EUV radiation. Radiation sensitivity and stability are important for organometallic photoresists.

The physical and chemical properties of organometallic compounds which are suitable for photoresists determine the relevant properties for photolithography, particularly for EUV and DUV, wherein bond dissociated energy (BDE) of M-C(metal-carbon bond) plays the key role. The metal-bonded organic ligands (M-R, M=metal, R=cleavable or hydrolysable organic ligands) may also influence the relevant absorption through M-C bonding. M is metal including but not limited to, tin (Sn), indium (In), antimony (Sb), bismuth (Bi), manganese (Mn), vanadium (V), titanium (Ti), chromium (Cr), selenium (Se), tellurium (Te), zirconium (Zr), hafnium (Hf), gallium (Ga), or germanium (Ge). Particularly, organometallic tin photoresists are suitable for EUV or DUV photolithography.

In general, metal central plays the key role in determining the absorption of photo radiation of organometallic photoresists. Tin atom provides strong absorption of extreme ultraviolet (EUV) light at 13.5 nm, therein tin cations can be selected based on the desired radiation and absorption cross section. The bond dissociation energy (BDE) of Sn—C bond determines the light adsorption wavelength, corresponding smaller features, and patterned structures. The organic ligand bonded to tin also has absorption of EUV light. Therefore, the tuning and modification of organic ligands can change sensitivity, radiation absorption, and the desired control of material properties.

Organometallic tin photoresists, including cycloalkenyl-containing such as (cyclopentadienyl)tin and (cycloheptatrienyl)tin compounds, may have excellent (e.g., suitable) sensitivity to high energy light (e.g., EUV, DUV, X-ray, or laser) due to tin strong absorption of extreme ultraviolet (EUV) at about 13.5 nm. Accordingly, organometallic tin photoresists may have improved sensitivity, resolution and stability compared to conventional organic polymer, or inorganic photoresists.

The general EUV photolithography process is: (1) depositing photoresist as a thin film over a substrate; (2) then pre-exposure baking; (3) exposing to EUV radiation to form a latent image; (4) after post-exposure baking; (5) then developing with a developer (e.g., aqueous basic/acid solutions or organic solvents); (6) and then rinsing with solvent to produce the developed resist pattern.

Wet and dry deposition or coating methods may be carried out over the surface of semiconductor substrate. The general wet coating of radiation sensitive organometallic photoresists on the surface of semiconductor substrate includes spin-on coating, spray coating, dip coating, vapor deposition, knife edge coating, inkjet printing, or screen printing, and the like.

In some embodiments, the conventional spin-on coating method is used for depositing organometallic photoresists over the surface of semiconductor substrates to form a thin film for photolithography. Under this circumstance, the followed procedure of post-apply backed (PAB) on a hot plate at ambient temperature like 100 C° under inert atmosphere (e.g., dinitrogen) with regular pressure will be controlled to avoid the potential photoresist sublimation at the point temperature and then decrease the thickness of photoresist, followed by defects generation or pattern collapses.

In some embodiments, organometallic photoresists may be deposited over the semiconductor substrate through dry deposition method like chemical vapor deposition, physical vapor deposition, or atomic layer deposition.

In some embodiments, the advantages of vapor or atomic layer deposition methods may improve the uniformity of thickness and composition, reduce the photoresist film defect density.

In some embodiments, organometallic photoresist precursors suitable for chemical vapor deposition or atomic layer deposition may form metal oxide film through decomposition, such as (cyclopentadienyl)hafnium and zirconium compounds.

In some embodiments, organometallic photoresists will not decompose at appropriate temperature under high vacuum, except sublimation or vaporization and then deposition over the surface of substrate. This is different from deposition by decomposition through chemical vapor deposition, physical vapor deposition, or atomic layer deposition method.

The development process is to either remove the exposed portion to form the positive tone pattern or unexposed portion to form negative tone pattern by different developer compositions. The contact of the patterned coating material or latent image with developer solvents will perform the target.

In some embodiments, the general wet developer compositions can be neutral, basic, acidic aqueous solutions, or organic solvents at low to high concentrations. The temperature for development process can be high or low. The temperature can be applied for the control of the rate or kinetics of development process as required.

In some embodiments, the general wet liquid solvent developer composition comprises an organic solvent blend. Non-limiting examples of organic solvents used in the method of forming patterns according to an embodiment may include, but not limited to, ketones (e.g., acetone, 2-heptanone, methylethylketone, cyclohexanone, 2-pyrrolidone, 1-ethyl-2pyrrolidone, and/or the like), alcohols (e.g., methanol, ethanol, 1-propanol, isopropanol, 1-butanol, 4-methyl-2-propanol, 1,2-propanediol, 1,2-hexanediol, 1,3-propanediol, pentanol, 2-heptanol, and/or the like), esters (e.g., ethyl acetate, n-butyl acetate, butyrolactone, propylene glycol methyl ether, ethylene glycol, propylene glycol, glycerol, ethylene glycol methyl ether, and/or the like), aromatic solvents (e.g., benzene, toluene, xylene), acid (e.g., formic acid, acetic acid, oxalic acid, 2-ethylhexanonic acid), and combinations thereof.

In some embodiments, the wet liquid solvent developing process is applied by dipping the exposed/unexposed substrates into a developer bath. In some embodiments, the wet solvent developing solution can be sprayed into the exposed/unexposed photoresists layer.

In general, after development the formed pattern coating can be heated to the range of 100-600° C. without pattern collapse. The heat can be carried out under air, inert atmosphere, or in vacuum.

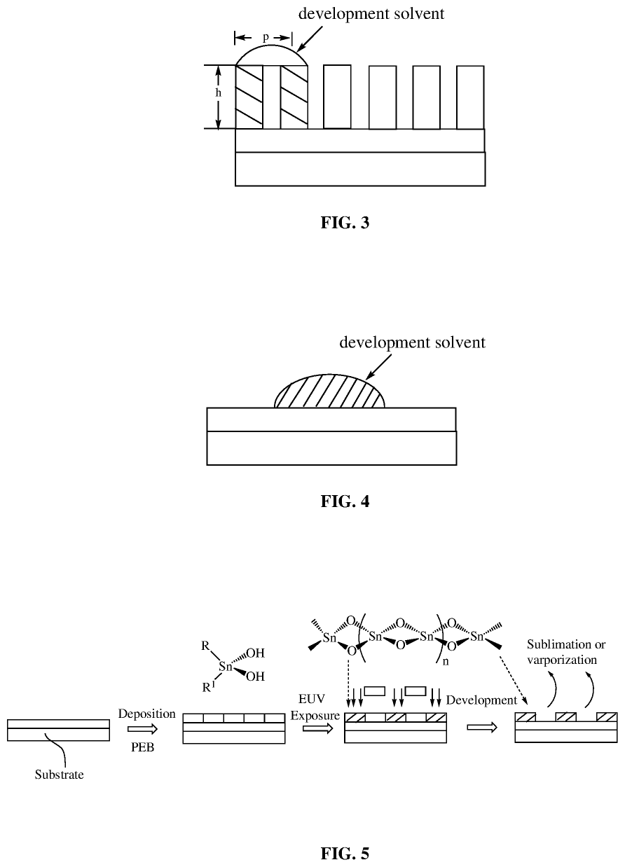

In some embodiments, for the patterned pitch <7 nm, while the thickness is 20 nm with the aspect ratio of 20-7, it may be difficult to remove the unexposed portion of photoresists by liquid solvents, as illustrated by FIG. 3. The wetting, surface tension and distorting force would make the conventional wet liquid development tough and much more difficulty for the smaller pitch and spaces like 1-3 nm, along with structure pattern collapses and defects, e.g., FIG. 4.

In some embodiments, radiation sensitive organometallic photoresists possessing sublimation or vaporization ability under ambient vacuum and temperatures are represented by RₐM_{b}L_{c}, wherein, R is organic group such as substituted or unsubstituted alkyl (linear or branched), alkenyl, alkynyl, cycloalkyl, or cycloalkenyl with 1 to 20 carbon atoms; M is a metal such as Sn, In, Sb, Bi, Mn, V, Ti, Cr, Se, Te, Zr, Hf, Ga, or Ge; and L is an organic ligand such as alkoxide, amide, ester, halide, hydroxide, nitride, oxide, or thiolate, and a, b, c≥1, for example, bis(cyclopentadienyl)tin oxide, bis(cyclopentadienyl)tin dihydroxide, bis(cyclopentadienyl)vanadium, or bis(cyclopentadienyl)manganese.

In some embodiments, R is a substituted or unsubstituted cycloalkenyl group with 3 to 20 carbon atoms, such as cyclopentadienyl, cycloheptatrienyl. In some embodiments, organometallic photoresists RₐM_{b}L_{c} are sandwich or half-sandwich compounds bearing π bond. In some embodiments, M is tin.

In some embodiments, cycloalkenyl group is a substituted and unsubstituted C4 to C8 cyclic unsaturated organic group including at least one double bond represented by following:

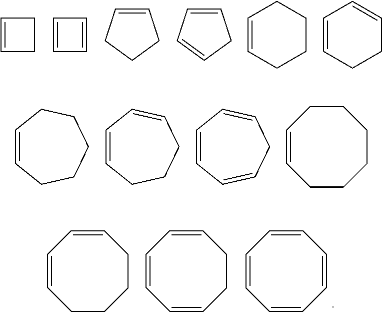

The desirable features of organometallic photoresists or precursors possess, sufficient volatility or sublimation ability for vapor-phase transportation, thermal stability to avoid the premature decomposition, and appropriate reactivity with co-precursor to form the target product under UV/EUV light radiation.

Herein, a method of developing photolithography patterning comprises: depositing organometallic photoresist composition over a substrate to form a photoresist layer; exposing organometallic photoresists layer to actinic radiation to form a latent pattern; and developing the latent pattern by applying sublimation or vaporization method to remove unexposed organometallic photoresist to form a photolithography pattern. The photosensitivity and thermostability of organometallic photoresists determine high resolution and efficiency of photolithography. For smaller pitch pattern structures such as <7 nm, the sublimation or vaporization development method may avoid the usage of plenty of solvents and related waste treatments, as well as increased cost and environment concerns.

After exposure to ultraviolet light, the exposed and unexposed portion possess different chemical and physical properties. The development of exposed or unexposed organometallic photoresist to form a high-resolution patterning is important for photolithography. The development process may be accomplished by sublimation or vaporization under ambient vacuum and temperature for the pattern development without pattern collapse. For example, the exposed portion converts to non-sublimized metal oxide. However, the unexposed portion still possesses the volatility property and may be removed by sublimation or vaporization under high vacuum and temperature. This method avoids the application of wet and dry developer, and/or rinse process, and improve the resolution and reduce the pattern collapse.

In some embodiments, the sublimation or vaporization is carried out under vacuum ranging from 0.0001 torr to 100 torr, and/or at a temperature ranging from 20° C. to 300° C.

In some embodiments, the sublimation and vaporization development methods may overcome disadvantages or drawbacks from wet development methods, such as potential pattern collapses and defects, related higher cost, waste solvents treatment, and environmental concerns like pollution control, because of dipping in organic solvents or aqueous solutions for development, rinsing by solvents for removal.

The properties of organometallic photoresists determine the availability of sublimation and vaporization development methods; wherein organometallic photoresists can be sublimized or vaporized under high vacuum at appropriate temperature like 20-300° C. without decomposition. While organometallic photoresists still possess radiation sensitive for photolithography patterning. The exposed portion of photoresists cannot be sublimized or vaporized under ambient vacuum and temperature.

The sublimation and vaporization development methods may enhance pattern fidelity and eliminate microbridge defects, due to no usage of liquid solvent or gaseous developers.

The sublimation and vaporization development methods may significantly improve the efficiency, resolution and products ratios, and while reduce the cost including environmental concerns and waste treatment like water consuming and waste water/organic solvent treatment.

In some embodiments, sublimation or vaporization ability and thermostability without decomposition under high vacuum and temperature for radiation sensitive organometallic photoresists play the key role in determining the development method. In particular, Group 13, 14 and 15 metals, such as Sn, In, Sb, have particular stability and processing effectiveness for radiation absorption.

In some embodiments, the organometallic photoresists expose to ultraviolet light such as EUV or DUV under inert atmosphere (e.g., dinitrogen or argon) with normal pressure without vacuum, in order to avoid potential sublimation or vaporization, pattern collapses, or defects.

In some embodiments, the exposed organometallic photoresists may be carried out radiation-induced oxidation in the presence of oxygen source atmosphere such as oxygen (O₂), ozone (O₃), hydrogen peroxide (H₂O₂), or water (H₂O) atmosphere. It may result in or enhance the oxidization of irradiated organometallic photoresist to form metal oxide or polymetallic oxide networks under some circumstances. Meanwhile, unexposed portion will not convert to oxide, oxo or hydroxyl network products, rather than sublimation or vaporization under high vacuum and temperature. This may require organometallic photoresists air- or water-stable, but when irradiation, the radiation reaction will occur to form oxide, oxo or hydroxyl network products.

In some embodiments, organometallic photoresist may be contacted with reactive gaseous atmosphere such as H₂S, SO₂, sulfur (S₈), carbon dioxide (CO₂), carbon monoxide (CO), HCOOH, ammonia (NH₃), PH₃, or SiH₄ under or after irradiation. It may increase the contrast between irradiated and unirradiated portions of organometallic photoresists.

In some embodiments, the sublimation and vaporization development methods may also be available for DUV, or FUV. This requires radiation sensitive organometallic photoresists at the levels which are suitable for DUV or FUV, according to E=hv=hc/λ and BDE (M-C), wherein E represents energy, h is plank constant, v is frequency, c is light speed, and λ is light wave length.

In some embodiments, the radiation sensitive organometallic photoresists comprise (cyclopentadienyl)metal complexes represented by (C₅R₅)ₓMR_{y}^{a}, wherein R is an alkyl, alkenyl, alkynyl, cycloalkyl, or aryl group; R^{a} is an alkyl, alkenyl, alkynyl, alkoxyl, amide, cycloalkenyl, ester, halide, hydroxide, silo, thiolate, or carbonyl group; M is metal including Sn, In, Sb, Bi, Mn, V, Ti, Cr, Se, Te, Zr, Hf, Ga, or Ge; x, y≥1. In some embodiments, (cyclopentadienyl)metal complexes (C₅R₅)ₓMR_{y}^{a} are sandwich or half sandwich complexes bearing η⁵-C₅-M π bond.

In some embodiments, organometallic photoresists comprising polyatomic metal oxo/hydroxyl cations with organic ligands are generally selected for radiation adsorption as EUV photoresists.

In some embodiments, a blend of volatile or sublimized-available organometallic photoresists may be performed in situ ultraviolet light-induced radiation reactions to form non-sublimized, non-volatile or insoluble complexes, including but not limited to oxo/hydroxyl, polyatomic complexes, metal oxo or hydroxyl network, organometallic polymer, in the presence of EUV/DUV light or electron beam, which possess the feature characterizes for small pitch like <7 nm. Meanwhile, the unexposed portion of the blend of volatile organometallic photoresists may be removed by high vacuum under ambient temperature like 20-300° C. However, without ultraviolet light, no reactions would occur under ambient conditions, including thermal or radiation reactions. In some embodiments, the in situ radiation reaction may be carried out in solvents like organic solvent, which is spray on the substrate surface after deposition of organometallic photoresists, or by spinning-on deposition as solution composition.

In some embodiments, a blend of organometallic photoresists may have identical and/or different metal centers, including but not limited to Sn, In, Sb, Bi, Mn, V, Ti, Cr, Se, Te, Zr, Hf, Ga, or Ge, for example, CpSnO(OH) with CpSn(OH)₃.

In some embodiments, the exposed portion of organometallic photoresists may be conducted by dry etch processing using dry BCl₃ plasma, hydrogen halides, hydrogen gas and halogen gas.

In some embodiments, organometallic photoresists comprise functional groups such as ether, thiol, silyl, keto, cyano, carbonyl, halogen groups, or combinations thereof.

In some embodiments, a blend of organometallic photoresist [M1] with organometallic photoresist [M2], or more, like photoresist [M3], will perform ultraviolet light-induced reaction. In some embodiments, M-M′ or M-O-M′ bond may be formed upon ultraviolet radiation, wherein M, M′ represent metal atoms. The formed products may have poor solubility in organic solvent or aqueous basic/acidic solution, without volatility under high vacuum and ambient temperature.

In some embodiments, upon exposing, organometallic photoresist [M1] may react with organometallic photoresist [M2] through hydrolysis or condensation to form a coating film comprising metal oxides or oxo/hydroxyl networks, which may not be removed by sublimation or vaporization under ambient vacuum and temperature. While the unexposed organometallic photoresist [M1] and [M2] may be removed by sublimation or vaporization under ambient vacuum and temperature to form the desired patterns without collapses or defects. For example, a blend of Cp₂Sn(OH)₂, CpSn(OH)₃, or CpSnO(OH) forms composition, and then converts to oxo or hydroxyl networks upon EUV irradiation.

In some embodiments, organometallic tin photoresists according to embodiments of the present disclosure may be represented by at least one of examples. Examples of specific organometallic tin photoresists or precursor materials that may be used in implementations of the invention are represented by FIG. 1. In some embodiments, R is a substituted or unsubstituted cycloalkenyl group, for example, cyclopentadienyl, or cycloheptatrienyl.

In some embodiments, cycloalkenyl-containing organometallic photoresists include, but not limited to (cyclopentadienyl)metal and (cycloheptatrienyl)metal compounds, such as oxide hydroxide, anhydride, hydroxide, alkoxide, oxo, amide, or ester, with hapticity of η¹, or η², or η³, or η₄, or η⁵, or η⁶, or η⁷ of isomers.

In some embodiments, organometallic tin photoresists or precursors include, but not limited to oxide hydroxide, anhydride, hydroxide, alkoxide, amide, ester, or oxo.

In some embodiments, organometallic tin photoresists contain cycloalkenyl group, such as (cyclopentadienyl)tin, (cycloheptatrienyl)tin. (Cyclopentadienyl)tin compounds comprise cyclopentadienyl C₅H₅ (or Cp) group, or substituted cyclopentadienyl C₅H₄R′, C₅H₃R′₂, C₅H₂R′₃, C₅HR′₄, or C₅R′₅ with hapticity of η¹, η², η³, η₄, or η⁵ of isomers. (Cycloheptatrienyl)tin compounds comprise cycloheptatrienyl C₇H₇ group, or substituted cycloheptatrienyl C₇H₆R′, C₇H₅R′₂, C₇H₄R′₃, C₇H₃R′₄, C₇HR′s, CHR′₆, or C₇R′₇ group with hapticity of η¹, η², η³, η₄, η⁵, η⁶, or η⁷ of isomers; wherein R′ is H, an alkyl, alkenyl, alkynyl, or cycloalkyl group with 1 to 20 carbon atoms, or an aryl group with 6-20 carbon atoms, or amino, cyano, ether, ester, halide, nitro, silyl, thiol, or carbonyl group. For example, R′ is methyl, ethyl, isopropyl, tert-butyl, tert-amyl, sec-butyl, pentyl, hexyl, neopentyl, cyclohexyl, cyclopentyl, cyclobutyl, cyclopropyl, phenyl, or benzyl.

In some embodiments, (cyclopentadienyl)tin compounds are η⁵-sandwich or half-sandwich compounds bearing η⁵-C₅—Sn π bond. In some embodiments, (cycloheptatrienyl)tin compounds are η⁷-sandwich or half-sandwich compounds bearing η⁷-C₇—Sn π bond.

Cyclopentadienyl group (C₅R′₅, or Cp) may impart photosensitivity to the compounds. The formed Cₚ—Sn bond may promote suitable solubility in organic solvent to cyclopentadienyl-containing organotin compound photoresist. Accordingly, Cₚ—Sn bond containing organotin compound photoresist, according to an embodiment, may have improved sensitivity, resolution, etch resistance, and stability, and may suitable for EUV photoresists, and/or the precursors for EUV lithography to form tin oxide or tin oxide hydroxide film.

Herein the disclosed (cyclopentadienyl)tin compounds contain cyclopentadienyl-Sn bond (Cₚ—Sn bond). Cₚ—Sn bond is sensitive to UV light and occurs the radiation disruption to generate free radical when exposures to UV light, which has been demonstrated, for example, P. J. Baker, A. G. Davies, M.-W. Tse, “The Photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅○ radical. This study demonstrated cyclopentadienyl (C₅H₅) group or substituted cyclopentadienyl (C₅R₅) group has higher UV light sensitivity compared with alkyl (e.g., methyl, butyl) group under identical condition. This property is beneficial to decrease EUV light dose and increase resolution.

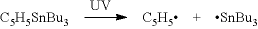

Therefore, organometallic tin photoresists bearing cycloalkenyl group and C_{cycloalkenyl}—Sn bond, such as cyclopentadienyl or substituted-cyclopentadienyl group bearing π bond, according to embodiments of the present disclosure, may have improved etch resistance, sensitivity, and resolution, compared with C_{alkyl}—Sn containing organotin photoresist.

Organometallic (cyclopentadienyl)tin and (cycloheptatrienyl)tin compounds contain T bond, C—Sn bond and related interaction and may have excellent (e.g., suitable) sensitivity to EUV radiation light due to tin adsorption high energy EUV ray at 13.5 nm. Accordingly, the related solution compositions may have improved sensitivity and stability compared with organic polymer or inorganic photoresists.

In some embodiments, the composition of organometallic tin photoresists, such as cycloalkenyl-containing (cyclopentadienyl)tin or (cycloheptatrienyl)tin photoresist, according to embodiments of the present disclosure, may have relatively improved etch resistance, sensitivity and resolution, wherein oxygen, nitrogen, or various groups are bonded to tin metal as described above, compared to conventional organic polymer photoresists and inorganic photoresists.

In some embodiments, organometallic (cyclopentadienyl)tin photoresists include, but not limited to, bi(cyclopentadienyl)tin hydroxide represented by chemical formula (C₅R₅)₂Sn(OH)₂, bi(cyclopentadienyl)tin alkoxides represented by chemical formula (C₅R₅)₂Sn(OR¹)(OR²), bi(cyclopentadienyl)tin oxo represented by chemical formula (C₅R₅)₂Sn(OR¹)(O)(C₅R₅)₂Sn(OR²), bi(cyclopentadienyl)tin amides represented by chemical formula (C₅R₅)₂Sn(NR₂¹)(NR₂²), bi(cyclopentadienyl)tin esters represented by chemical (C₅R₅)₂Sn(OCOR¹)(OCOR²), (cyclopentadienyl)tin oxide hydroxide (stannonic acid) represented by chemical formula (C₅R₅)SnO(OH); (cyclopentadienyl)tin acid ester represented by chemical formula (C₅R₅)SnO(OR¹); (cyclopentadienyl)tin acid anhydrides represented chemical formula [(C₅R₅)SnO]20; (cyclopentadienyl)tin hydroxides and alkoxides represented by chemical formula (C₅R₅)Sn(OR¹)(OR²)(OR³); (cyclopentadienyl)tin oxo represented by chemical formula [(C₅R₅)Sn(OR¹)(OR²)]2(O); (cyclopentadienyl)tin amides represented by chemical formula (C₅R₅)Sn(NR₂¹)(NR₂²)(NR₂³); (cyclopentadienyl)tin esters represented by chemical formula (C₅R₅)Sn(OCOR¹)(OCOR²)(OCOR³), with hapticity of η¹, η², η³, η₄, or η⁵ of isomers; wherein R, R¹, R², R³ are is independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms.

In some embodiments, organometallic (cycloheptatrienyl)tin photoresists comprise (cycloheptatrienyl)tin oxide hydroxide represented by chemical formula (C₇R₇)SnO(OH); (cycloheptatrienyl)tin acid ester represented by chemical formula (C₇R₇)SnO(OR¹); (cycloheptatrienyl)tin acid anhydrides represented by chemical formula [(C₇R₇)SnO]₂O; (cycloheptatrienyl)tin hydroxides and alkoxides represented by chemical formula (C₇R₇)Sn(OR¹)(OR²)(OR³); (cycloheptatrienyl)tin oxo represented by chemical formula [(C₇R₇)Sn(OR¹)(OR²)]2(O); (cycloheptatrienyl)tin amides represented by chemical formula (C₇R₇)Sn(NR₂¹)(NR₂²)(NR₂³); (cycloheptatrienyl)tin esters represented by chemical formula (C₇R₇)Sn(OCOR¹)(OCOR²)(OCOR³), with hapticity of η¹, η², η³, η⁴, η⁵, η⁶, or η⁷ of isomers; wherein R, R¹, R², R³ are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms.

The methods for purification of organometallic photoresist compounds comprise distillation, extraction, filtration, recrystallization, column chromatography, coordination, sublimation, or combinations thereof.

In some embodiments, organometallic photoresists are soluble in appropriate organic solvents for further photolithography pattern processing like spin-on coating. The solution compositions of organometallic photoresists may be formed by dissolving organometallic photoresists in organic solvents, including but not limit to, chloroform, tetrahydrofuran, dimethoxyethane, dimethylformamide, dimethyl sulfoxide, alcohols (e.g., 4-methyl-2-pentenol, ethanol, methanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. The solution composition of organometallic photoresists may be utilized for photolithography like EUV, DUV for further processing and patterning.

In some embodiments, the solubility of organometallic tin photoresists such as cycloalkenyl-containing in organic solvents, may be improved, and dissolution during an extreme ultraviolet (EUV) exposure. Accordingly, a nanoscale pattern having improved sensitivity and limited resolution may be afforded by using of cycloalkenyl-containing photoresists. Additionally, the as-formed pattern by using of cycloalkenyl-containing photoresists may not collapse while having a high aspect ratio.

In some embodiments, organometallic tin photoresists such as cycloalkenyl-containing may have high sensitivity (low expose dose photoresist, e.g., <20 mJ/cm²) and toughness; low or free pattern defectivity at nanoscale. Cycloalkenyl-containing organometallic tin photoresist may have tight pitch (e.g., <10 nm), and may sustain the yield and deliver high resolution.

In some embodiments, organometallic photoresists composition may also contain additives such as resin, in addition to photoresists and organic solvents.

In some embodiments, the resin may be organic polymer, and/or small organic aromatic molecules. In some embodiments, the resin may be volatile under ambient vacuum and temperature.

In addition, organometallic photoresists patterning according to an embodiment is not necessarily limited to the negative tone image but may be formed to have a positive tone image.

In some embodiments, after exposure, organometallic photoresists absorb the ultraviolet radiation, organic ligand groups can be cleaved from organometallic photoresists to form metal oxide or polymetallic oxide/oxo pattern. The unexposed portion of the substrate surface may be removed by the sublimation or vaporization develop method without pattern collapses or defects.

Hereinafter, the present invention is described more embodiments regarding organometallic photoresist. The preparation of organometallic photoresists depend on synthetic strategies and reaction conditions. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the sprit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organometallic photoresist representing by chemical formula RₐM_{b}L_{c}, wherein R is a substituted or unsubstituted cycloalkenyl group with 3 to 20 carbon atoms; M is metal including Sn, In, Sb, Bi, Mn, V, Ti, Cr, Se, Te, Zr, Hf, Ga, or Ge; L is an alkoxide, amide, ester, halide, hydroxide, or thiolate group; a, b, c≥1.

2. The organometallic photoresist of claim 1, wherein cycloalkenyl is a substituted or unsubstituted C4 to C8 cyclic unsaturated organic group including at least one double bond.

3. The organometallic photoresist of claim 2, wherein cycloalkenyl is one or more selected from the following:

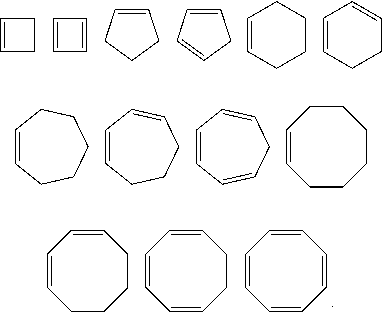

4. The organometallic photoresist of claim 1, wherein R is cyclopentadienyl C₅H₅ group, or substituted cyclopentadienyl C₅H₄R′, C₅H₃R′₂, C₅H₂R′₃, C₅HR′₄, or C₅R′₅ group with hapticity of η¹, η², η³, η⁴, or η⁵ of isomers; wherein R′ is a substituted or unsubstituted alkyl, alkenyl, alkynyl, cycloalkyl, or cycloalkenyl group with 1 to 20 carbon atoms, or a substituted or unsubstituted aryl group with 6-20 carbon atoms.

5. A method of developing photolithography patterning, comprising:
depositing organometallic tin photoresist composition over a substrate to form a photoresist layer;
exposing organometallic tin photoresists layer to actinic radiation to form a latent pattern; and
developing the latent pattern by applying sublimation or vaporization method to remove unexposed organometallic tin photoresist to form a photolithography pattern.

6. The method of claim 5, wherein the organometallic tin photoresist is one or more selected from the following: 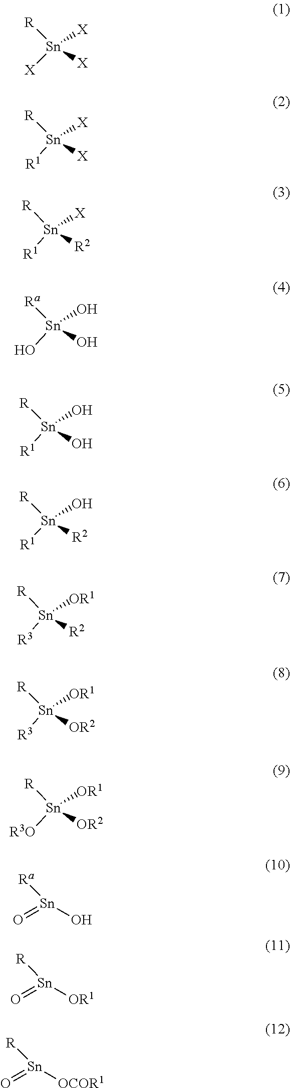 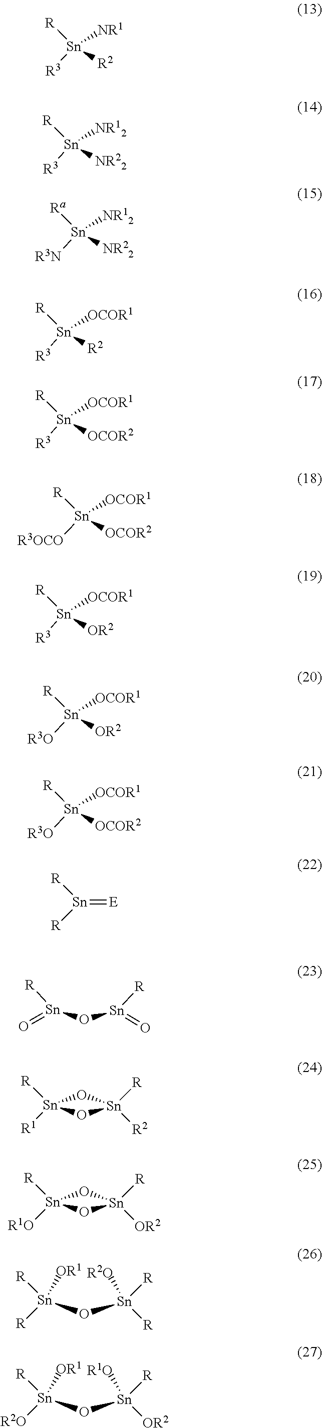
wherein R is a substituted or unsubstituted cycloalkenyl group selected from the following; 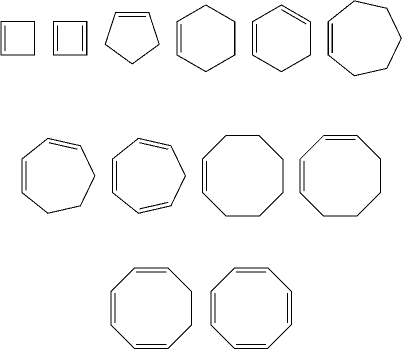
R¹, R², R³ are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; X=F, Cl, Br, or I; E=O, S, Se, or Te.

7. The method of claim 6, wherein R¹, R², R³ are each independently a substituted or unsubstituted alkyl group, cyclopentadienyl C₅H₅ group, or substituted cyclopentadienyl C₅H₄R′, C₅H₃R′₂, C₅H₂R′₃, C₅HR′₄, or C₅R′₅ group with hapticity of η¹, η², η³, η₄, or η⁵ of isomers, wherein R′ is a substituted or unsubstituted alkyl, alkenyl, alkynyl, or cycloalkyl group with 1 to 20 carbon atoms, or a substituted or unsubstituted aryl group with 6-20 carbon atoms.

8. The method of claim 6, wherein R is cycloheptatrienyl C₇H₇ group, or substituted cycloheptatrienyl C₇H₆R′, C₇H₅R′₂, C₇H₄R′₃, C₇H₃R′₄, C₇H₂R′₅, C₇HR′₆, or C₇R′₇ group with hapticity of η¹, η², η³, η₄, η⁵, η⁶, or η⁷ of isomers; wherein R′ is a substituted or unsubstituted alkyl, alkenyl, alkynyl, or cycloalkyl group with 1 to 20 carbon atoms, or a substituted or unsubstituted aryl group with 6-20 carbon atoms.

9. The method of claim 8, wherein R′ is a methyl, ethyl, propyl, n-butyl, t-butyl, phenyl, or benzyl group.

10. The method of claim 5, wherein organometallic tin photoresists are deposited over a surface of semiconductor substrate by chemical vapor deposition, physical vapor deposition, atomic layer deposition, or spin-on coating.

11. The method of claim 5, wherein the sublimation or vaporization is carried out under vacuum ranging from 0.0001 torr to 100 torr, and/or a temperature ranging from 20° C. to 300° C.

12. The method of claim 5, wherein the actinic radiation is extreme ultraviolet radiation, deep ultraviolet radiation, e-beam radiation, X-ray radiation, or ion-beam radiation.

13. The method of claim 5, wherein the exposing organometallic tin photoresists layer to actinic radiation may be under air, oxygen, ozone, hydrogen peroxide, or water atmosphere.

14. The method of claim 5, wherein the photolithography patterning may be under reactive gaseous H₂S, SO₂, S₈, CO₂, CO, HCOOH, NH₃, PH₃, or SiH₄ atmosphere.

15. An organometallic tin photoresist composition, comprising an organometallic tin compound, a solvent, and/or an additive;
wherein the organometallic tin compound is one or more selected from the following: 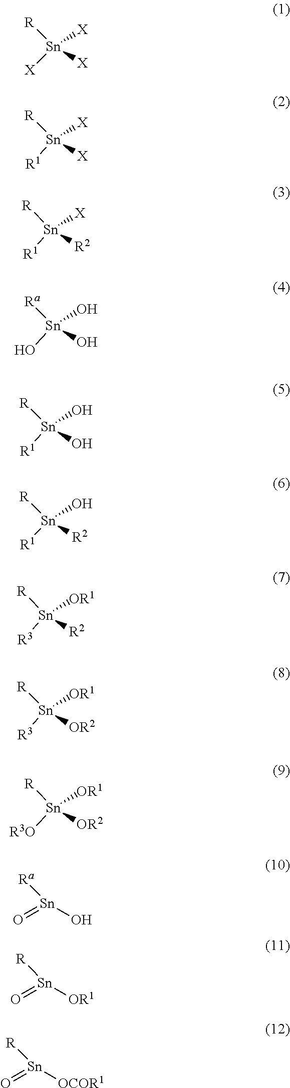 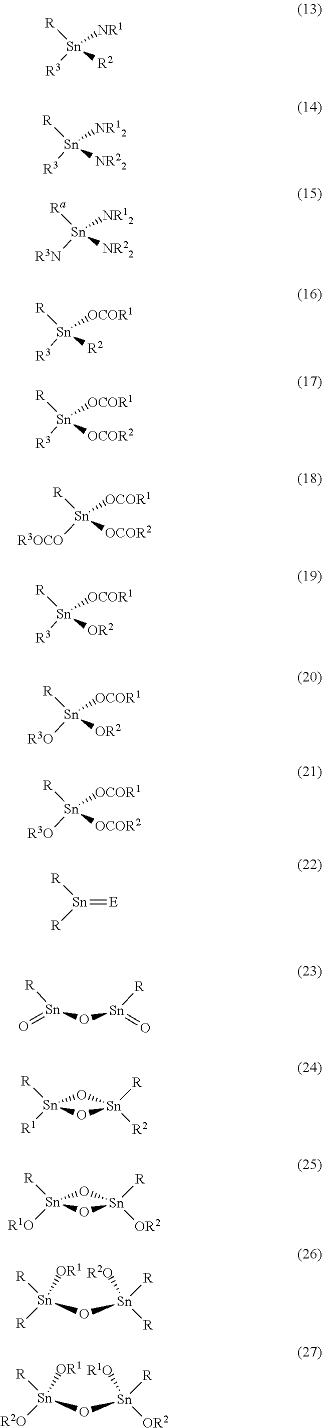
wherein R is a cycloheptatrienyl group; R¹, R², R³ are each independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; X=F, Cl, Br, or I; E=O, S, Se, or Te.

16. The organometallic tin photoresist composition of claim 15, wherein cycloheptatrienyl comprises cycloheptatrienyl C₇H₇ group, or substituted cycloheptatrienyl C₇H₆R′, C₇H₅R′₂, C₇H₄R′₃, C₇H₃R′₄, C₇H₂R′₅, C₇HR′₆, or C₇R′₇ group with hapticity of η¹, η², η³, η₄, η⁵, η⁶, or η⁷ of isomers; wherein R′ is a substituted or unsubstituted alkyl, alkenyl, alkynyl, or cycloalkyl group with 1 to 20 carbon atoms, or a substituted or unsubstituted aryl group with 6-20 carbon atoms.

17. The organometallic tin photoresist composition of claim 15, wherein R¹, R², R³ are each independently a substituted or unsubstituted alkyl, or cycloalkenyl group with 1 to 20 carbon atoms.

18. The organometallic tin photoresist composition of claim 17, wherein R¹, R², R³ are each independently an alkyl C₁-C₅, cyclopentadienyl C₅H₅, or substituted cyclopentadienyl C₅H₄R′, C₅H₃R′₂, C₅H₂R′₃, C₅HR′₄, or C₅R′₅ with hapticity of η¹, η², η³, η₄, or η⁵ of isomers, wherein R′ is a methyl, ethyl, propyl, n-butyl, t-butyl, phenyl, or benzyl group.
